(19) United States
(12) Patent Application Publication
(10) Pub. No.: US 2016/0359297 A1
(43) Pub. Date: Dec. 8, 2016

(54) MULTIPLE ENDPOINT OPTICAL TRANSMITTER

(71) Applicant: Alcatel-Lucent USA Inc., Murray Hill, NJ (US)

(72) Inventor: Joseph J. Kakande, Jersey City, NJ (US)

(21) Appl. No.: 14/728,915

(22) Filed: Jun. 2, 2015

(51) Int. Cl. H01S 5/042; H01S 5/42

(52) U.S. Cl. CPC H01S 5/042; H01S 5/423

(57) ABSTRACT

A multi-endpoint optical transmitter includes a first laser to couple to a first optical fiber, a second laser to couple to a second optical fiber, and a current-steered driver connected to the first and second lasers. The current-steered driver is to provide a first current representative of a bitstream to drive the first laser and to provide a second current representative of a complement of the bitstream to drive the second laser.

### CROSS REFERENCE TO RELATED APPLICATIONS

This application is related to U.S. patent application Ser. No. ______ (Attorney Docket No. 4100-817288-US), entitled “A MULTI-ENDPOINT OPTICAL RECEIVER” and filed on even date herewith, the entirety of which is incorporated by reference herein.

### BACKGROUND

### Field of the Disclosure

The present disclosure relates generally to optical networks and, more particularly, to optical transmitters in optical networks.

### Description of the Related Art

The efficiency and flexibility of an optical network can be improved by dynamically switching physical (and logical) endpoints associated with ports in the optical network. For example, dynamic optical routing can be used to adjust the bandwidth between optical network nodes (e.g., electronic routers) on demand to meet application requirements. For another example, aggregation switches and distribution switches in a data center can be interconnected with redundant sets of high-bandwidth optical fibers. Each optical fiber that connects an aggregation switch to a distribution switch is paired with a redundant optical fiber that connects the distribution switch to another (redundant) aggregation switch. The redundant optical fiber may be used for communication between the aggregation switches and the distribution switches in the event that the primary optical fiber fails or is otherwise unavailable. Optical transceivers connect the optical fibers to the electronic switches or routers. The optical transceivers include multiple transmitters to provide the same bitstream on the primary optical fiber and the redundant optical fiber. However, generating multiple bitstreams for transmission over the primary and redundant optical fibers may increase the design complexity of the transmitters, the capital cost of fabricating the transmitters, and the power consumption of the transmitters.

### SUMMARY OF EMBODIMENTS

The following presents a summary of the disclosed subject matter in order to provide a basic understanding of some aspects of the disclosed subject matter. This summary is not an exhaustive overview of the disclosed subject matter. It is not intended to identify key or critical elements of the disclosed subject matter or to delineate the scope of the disclosed subject matter. Its sole purpose is to present some concepts in a simplified form as a prelude to the more detailed description that is discussed later.

In some embodiments, an apparatus is provided for multi-endpoint optical transmission. The apparatus includes a first laser to couple to a first optical fiber, a second laser to couple to a second optical fiber, and a current-steered driver connected to the first and second lasers. The current-steered driver is to provide a first current representative of a bitstream to drive the first laser and a second current representative of a complement of the bitstream to drive the second laser.

In some embodiments, a method is provided for multi-endpoint optical transmission. The method includes providing, from a current-steered driver, a first current representative of a bitstream to drive a first laser coupled to a first optical fiber and a second current representative of a complement of the bitstream to drive a second laser coupled to a second optical fiber.

In some embodiments, an apparatus is provided for multi-endpoint optical transmission. The apparatus includes a plurality of lasers to couple to a corresponding plurality of optical fibers and a current-steered driver connected to the plurality of lasers. The current-steered driver is to selectively provide first currents representative of a bitstream to drive a first portion of the plurality of lasers and second currents representative of a complement of the bitstream to drive a second portion of the plurality of lasers.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of an optical network that implements single endpoint transceivers according to some embodiments.

FIG. 2 is a block diagram of an optical network that implements multi-endpoint transceivers according to some embodiments.

FIG. 3 is a block diagram of an optical communication system including a dual endpoint optical transmitter according to some embodiments.

FIG. 4 is a block diagram of a dual endpoint transceiver including a radiofrequency splitter for splitting a signal in the electrical domain according to some embodiments.

FIG. 5 is a block diagram of a dual endpoint transceiver including an optical splitter for splitting a signal in the optical domain according to some embodiments.

FIG. 6 is a block diagram of a dual endpoint transceiver including a current-steered driver according to some embodiments.

FIG. 7 is a block diagram of a driver for driving a directly modulated voltage controlled surface emitting laser (VCSEL) according to some embodiments.

FIG. 8 is a block diagram of a current-steered driver for driving a directly modulated VCSEL according to some embodiments.

FIG. 9 is a block diagram of a current-steered driver that includes a dummy impedance according to some embodiments.

FIG. 10 is a block diagram of a current-steered driver that includes matched VCSELs according to some embodiments.

FIG. 11 is a block diagram of a current-steered driver that drives matched VCSELs in response to complementary bitstream values according to some embodiments.

FIG. 12 is a block diagram of a current-steered driver that drives matched VCSELs using a transistor-based switch according to some embodiments.

FIG. 13 is a block diagram of a current-steered driver that drives matched VCSELs with different drive currents according to some embodiments.

### DETAILED DESCRIPTION

The complexity, capital cost, and power consumption of optical transmitters implemented in endpoints of optical networks can be reduced by implementing a multiple-endpoint optical transmitter. Some embodiments of the multiple-endpoint optical transmitter are dual-endpoint optical transmitters that include a first laser for coupling to a first optical fiber and a second laser for coupling to a second optical fiber. The first and second lasers may be vertical-cavity surface-emitting lasers (VCSELs), edge emitting lasers (EELs), or other types of coherent light sources. A current steered driver is connected to the first and second lasers to provide a first electrical signal representative of a bitstream to the first laser and a second electrical signal representative of the bitstream to the second laser. The second electrical signal is complementary to the first electrical signal. As used herein, the term “current-steered driver” refers to logic or other circuitry that can provide drive currents to one or more lasers while maintaining a substantially constant total current flow through the current-steered driver independent of the on/off state of the lasers. As used herein, the term “substantially constant” indicates that the total current remains constant within predetermined tolerances that allow for transient fluctuations that are smaller than the total current.

Some embodiments of the current steered driver include first, second, and third current sources. The first laser is coupled to the first current source and to a first transistor (or other switch) that is coupled to the second current source. The second laser is coupled to the third current source and a second transistor (or other switch) that is coupled to the second current source. A signal representative of the bitstream is provided to a gate of the first transistor and a signal representative of the inverse of the bitstream is provided to a gate of the second transistor. The first and second current sources provide an ON current to the first laser when the first transistor is enabled and an OFF current when the first transistor is disabled. The second and third current sources provide an ON current to the second laser when the second transistor is enabled and an OFF current when the second transistor is disabled. Some embodiments of the dual-endpoint optical transmitter include additional transistors and current sources to provide different ON currents to the first and second lasers. Some embodiments of the dual-endpoint optical transmitter provide signals to support polarity detection in an optical receiver that receives the second electrical signal.

FIG. 1 is a block diagram of an optical network 100 according to some embodiments. The optical network 100 includes endpoints 101, 102, 103, 104, which may be referred to collectively as “the endpoints 101-104.” In some embodiments of the optical network 100, the endpoints 101-104 may be optical network nodes such as electronic routers that are used to route optical signals in the optical network 100. Some embodiments of the optical network 100 may be implemented in a data center and the endpoints 101-104 may be switches. For example, the endpoints 101, 102 may be aggregation switches and the endpoints 103, 104 may be distribution switches. The endpoints 101, 102 can exchange optical signals with other entities (not shown) in the optical network 100 via optical fibers 105, 110, respectively. Some embodiments of the endpoints 101, 102 may be redundant endpoints 101, 102 that receive and transmit the same signals over the corresponding sets of optical fibers 105, 110. The endpoints 103, 104 exchange signals with compute (C) nodes 115 (only one indicated by a reference numeral in the interest of clarity).

The endpoints 101, 102 are interconnected with the endpoints 103, 104 using an optical fiber network that includes primary optical fibers 120, 121, 122, 123 (indicated by solid lines and which may be referred to as “the primary optical fibers 120-123”) and redundant or secondary optical fibers 125, 126, 127, 128 (indicated by dashed lines and which may be referred to as “the redundant optical fibers 125-128”). Each of the primary optical fibers 120-123 and the redundant optical fibers 125-128 are coupled to the corresponding endpoints 101-104 by a single (S) endpoint transceiver 130 (only one indicated by a reference numeral in the interest of clarity). The single endpoint transceivers 130 implement separate transmitters and, as discussed herein, the resulting duplication of the transmission logic associated with the primary optical fibers 120-123 and the redundant optical fibers 125-128 increases the design complexity of the transmitters, the capital cost of fabricating the transmitters, the power consumption of the transmitters, and the power consumed by the endpoints 101-104.

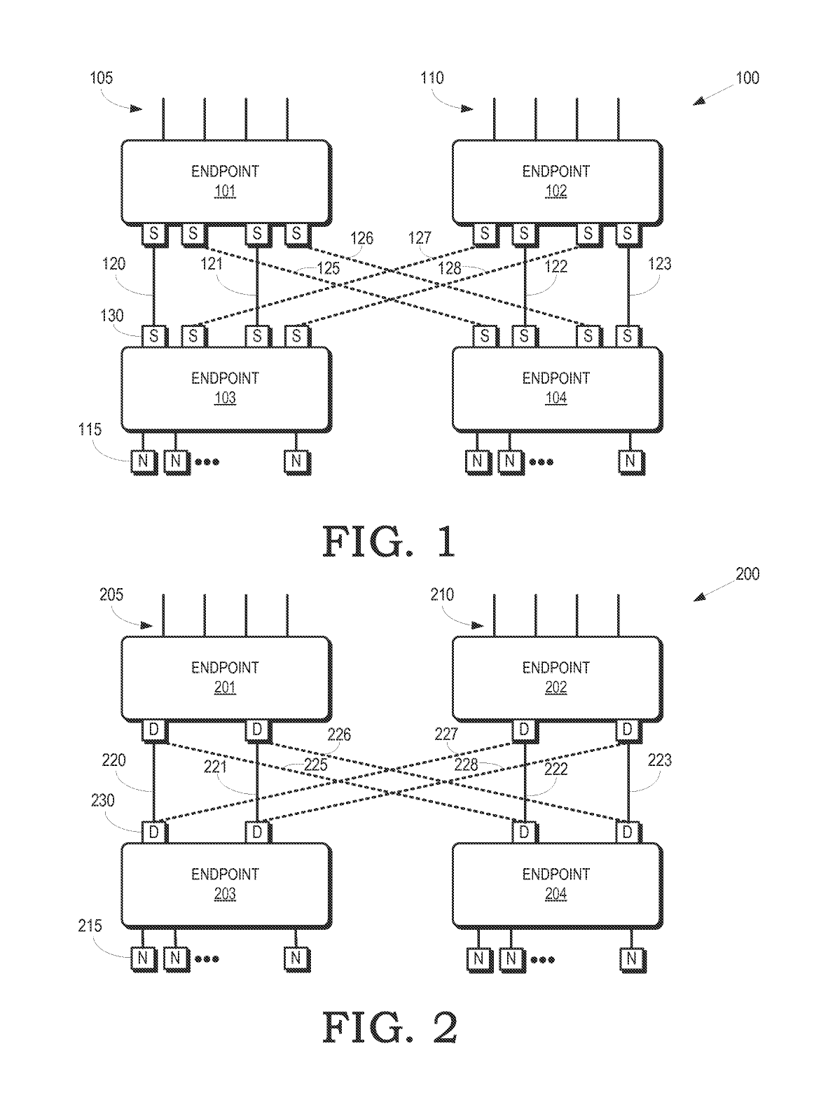

FIG. 2 is a block diagram of an optical network 200 according to some embodiments. The optical network 200 includes endpoints 201, 202, 203, 204, which may be referred to collectively as “the endpoints 201-204.” As discussed herein, the endpoints 201-204 may be optical network nodes such as electronic routers, aggregation switches, or distribution switches. The endpoints 201, 202 can exchange optical signals with other entities (not shown) in the optical network 200 via optical fibers 205, 210, respectively. Some embodiments of the endpoints 201, 202 may be redundant endpoints 201, 202 that receive and transmit the same signals over the corresponding sets of optical fibers 205, 210. The endpoints 203, 204 exchange signals with compute (C) nodes 215 (only one indicated by a reference numeral in the interest of clarity). The endpoints 201, 202 are interconnected with the endpoints 203, 204 using an optical fiber network that includes primary optical fibers 220, 221, 222, 223 (indicated by solid lines and which may be referred to as “the primary optical fibers 220-223”) and redundant or secondary optical fibers 225, 226, 227, 228 (indicated by dashed lines and which may be referred to as “the redundant optical fibers 225-228”).

The embodiment of the optical network 200 depicted in FIG. 2 differs from the embodiment of the optical network 100 depicted in FIG. 1 because each of the primary optical fibers 220-223 and a corresponding one of the redundant optical fibers 225-228 are coupled to a dual (D) endpoint transceiver 230 (only one indicated by a reference numeral in the interest of clarity). The dual endpoint transceivers 230 implement dual-endpoint transmitters for the primary and redundant optical fibers using consolidated logic that reduces the duplication of resources relative to a pair of single endpoint transceivers such as the single endpoint transceivers 130 shown in FIG. 1. Consequently, the capital cost of the endpoints 201-204 and the power consumed by the endpoints 201-204 may be significantly reduced relative to the corresponding endpoints 101-104 shown in FIG. 1. Some embodiments of the dual endpoint transceivers 230 may include a current-steered driver that provides drive currents to two or more lasers that are coupled to corresponding optical fibers. For example, the current-steered driver in a dual-endpoint transceiver 230 may provide a first current representative of a bitstream to drive the first laser and a second current representative of a complement of the bitstream to drive the second laser. The first and second lasers may be vertical-cavity surface-emitting lasers (VCSELs).

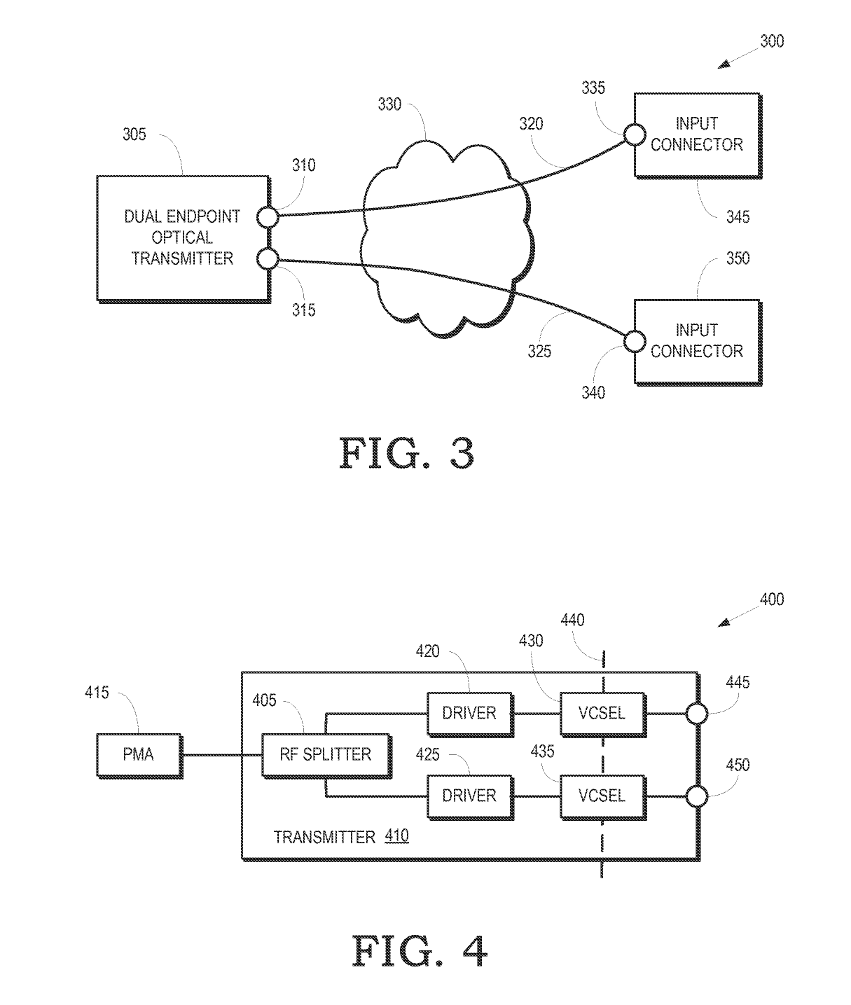

FIG. 3 is a block diagram of an optical communication system 300 including a dual endpoint optical transmitter 305 according to some embodiments. The dual endpoint optical transmitter 305 includes two optical ports 310, 315 that are coupled to corresponding optical fibers 320, 325 that traverse an optical network 330. The optical fibers 320, 325 are coupled to corresponding optical ports 335, 340 in input connectors 345, 350. The dual endpoint optical transmitter 305 includes a current-steered driver that provides complementary drive signals to drive two lasers that provide optical signals via the two optical ports 310, 315. However, some embodiments of the optical transmitter 305 may implement a current-steered driver that provides drive signals to additional lasers that generate optical signals for transmission via additional optical ports.

The optical signal transmitted through the optical port 310 is complementary to the optical signal transmitted through the optical port 315. For example, if the optical signal transmitted through the optical port 310 is representative of a bit having a value of “1,” than the optical signal transmitted through the optical port 315 is representative of a bit having a value of “0.” The input connectors 345, 350 may therefore implement polarity detection to determine if the polarity of the received bitstream has been inverted or is complementary to the expected polarity of the bitstream. If so, the input bitstream may be inverted by the input connectors 345, 350. Polarity detection mechanisms are known in the art and may include handshaking sequences to determine the polarity of the signal, higher layer signaling to indicate which optical signal is representative of the complement of the bitstream, and the like.

FIG. 4 is a block diagram of a dual endpoint transceiver 400 including a radiofrequency splitter 405 for splitting a signal in the electrical domain according to some embodiments. The dual endpoint transceiver 400 includes a dual endpoint transmitter 410 that is connected to a data link physical medium attachment (PMA) 415. The radiofrequency splitter 405 receives electrical radiofrequency signals from the PMA 415 and splits the electrical radiofrequency signals into two copies that are provided to corresponding drivers 420, 425. The drivers 420, 425 are connected to corresponding VCSELs 430, 435 that convert the electrical signals into optical signals. The VCSELs 430, 435 therefore represent a border between the electrical domain (to the left of line 440) and the optical domain (to the right of line 440). The optical signals are provided to output connectors 445, 450. The dual endpoint transceiver 400 has a number of drawbacks relative to single endpoint transceivers. For example, the radiofrequency splitter 405 and the additional driver 425 introduce additional complexity into the design of the dual endpoint transceiver 400. For another example, integrating two discrete drivers 420, 425 on a single integrated circuit chip can generate electrical crosstalk between the two transmission paths corresponding to the drivers 420, 425.

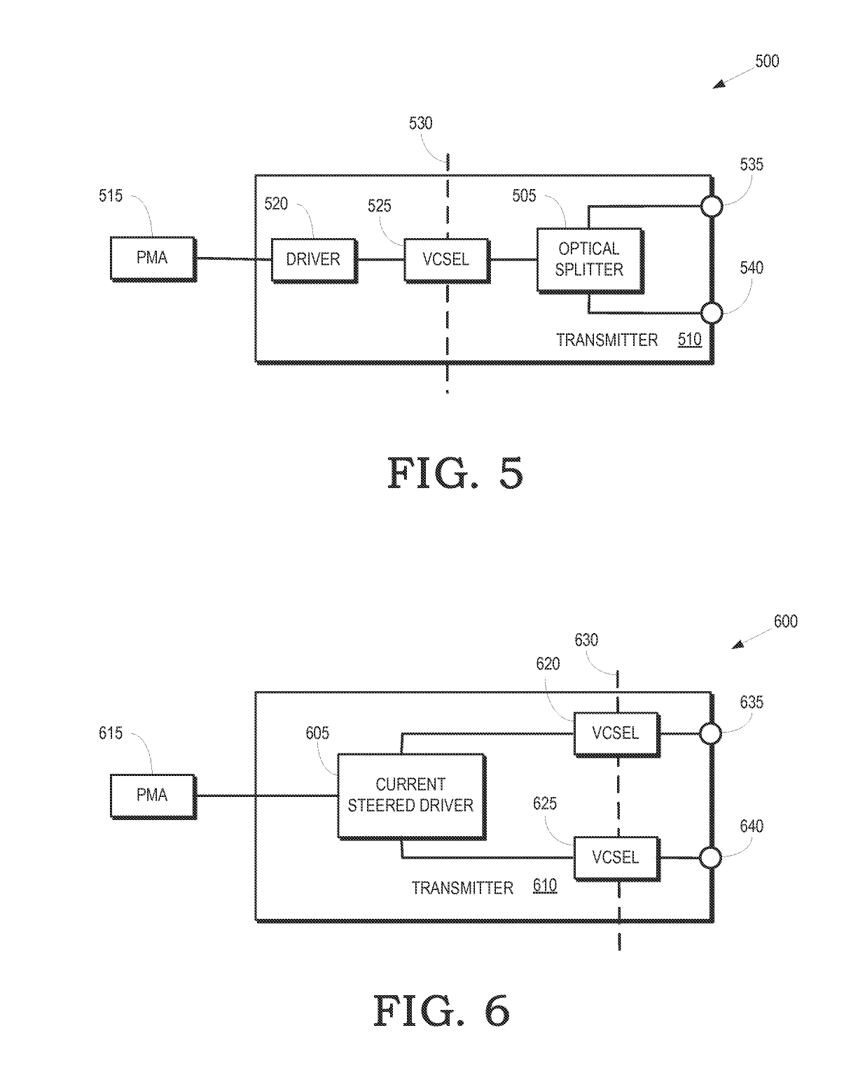

FIG. 5 is a block diagram of a dual endpoint transceiver 500 including an optical splitter 505 for splitting a signal in the optical domain according to some embodiments. The dual endpoint transceiver 500 includes a dual endpoint transmitter 510 that is connected to a data link PMA 515. A driver 520 in the transmitter 510 receives electrical signals from the PMA 515 and provides an electrical drive signal to a VCSEL 525. The VCSEL 525 converts the electrical signal into an optical signal. The VCSEL 525 therefore represents a border between the electrical domain (to the left of line 530) and the optical domain (to the right of line 530). The optical signal is provided to the optical splitter 505, which divides the optical signal into two copies that are provided to output connectors 535, 540. The dual endpoint transceiver 500 has a number of drawbacks relative to single endpoint transceivers. For example, losses in the optical splitter 505 may be a least 3 dB, which reduces the system margin. For another example, integrating the optical splitter 505 into the transit the design may not be straightforward, particularly in designs using integrated optical process technologies.

FIG. 6 is a block diagram of a dual endpoint transceiver 600 including a current-steered driver 605 according to some embodiments. The dual endpoint transceiver 600 may be implemented in some embodiments of the dual endpoint transceivers 230 shown in FIG. 2 or the dual endpoint optical transmitter 305 shown in FIG. 3. The dual endpoint transceiver 600 includes a dual endpoint transmitter 610 that is connected to a data link PMA 615. The current-steered driver 605 receives electrical signals from the PMA 615 and provides electrical drive signals to a pair of VCSELs 620, 625. The VCSELs 620, 625 convert the electrical signals into optical signals. The VCSELs 620, 625 therefore represent a border between the electrical domain (to the left of line 630) and the optical domain (to the right of line 630). The optical signals are provided to output connectors 635, 640. The dual endpoint transceiver 600 has a number of advantages over single endpoint transceivers or the embodiments of dual endpoint transceivers depicted in FIG. 4 and FIG. 5. For example, the dual endpoint transceiver 600 can be implemented using low complexity designs, can be integrated on integrated circuit chips, and experiences relatively low losses, as discussed herein.

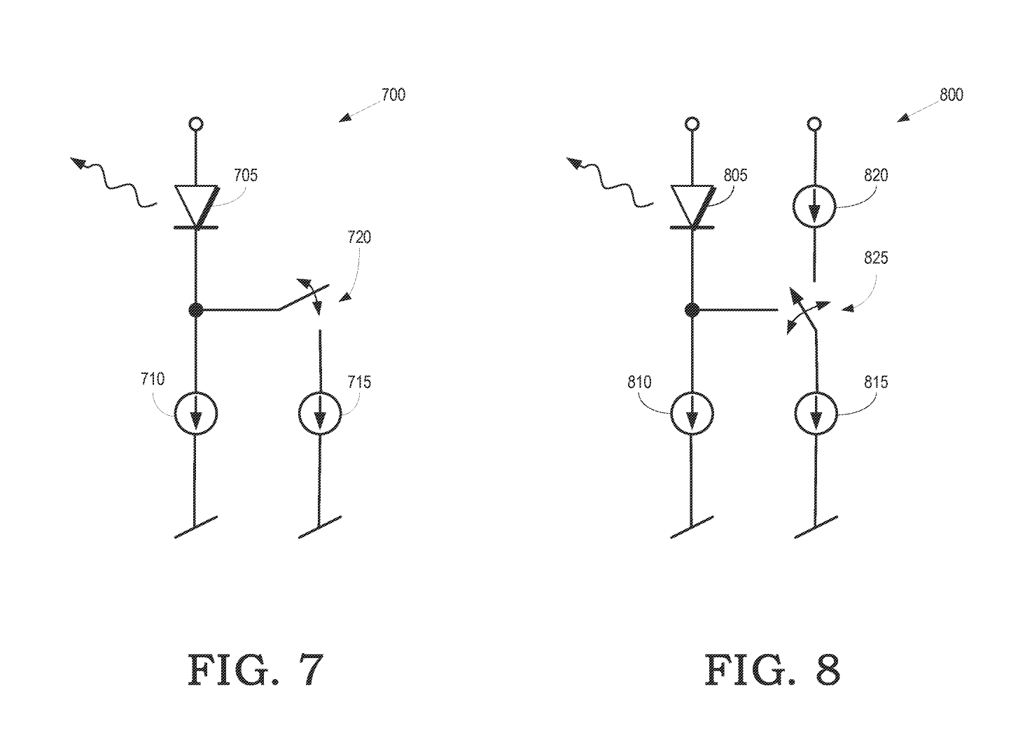

FIG. 7 is a block diagram of a driver 700 for driving a directly modulated VCSEL 705 according to some embodiments. The driver 700 includes a first current source 710 to provide a bias current I_{off} that corresponds to the OFF state of the VCSEL 705. In some embodiments, the bias current I_{off} is set to a level that is just above a threshold current Iₜₕ for the VCSEL 705. The driver 700 also includes a second current source 715 to provide a current Iₒₙ−I_{off} so that the sum of the currents provided by the first current source 710 and the second current source 715 provide the drive current Iₒₙ that corresponds to the ON state of the VCSEL 705.

A switch 720 is used to selectively connect the VCSEL 705 to the first current source 710 or the second current source 715. For example, in the OFF state, the switch 720 is open so that the VCSEL 705 is only connected to the first current source 710 and the bias current I_{off} is driving the VCSEL 705. In the ON state, the switch 720 is closed so that the VCSEL 705 is connected to both the first current source 710 and the second current source 715. Thus, the VCSEL 705 receives the drive current Iₒₙ that corresponds to the ON state of the VCSEL 705. The total current flowing through the drivers 700 fluctuates between I_{off} and Iₒₙ, which generates substantial noise due to the interaction between the fluctuating current and on-chip passive parasitics.

FIG. 8 is a block diagram of a current-steered driver 800 for driving a directly modulated VCSEL 805 according to some embodiments. The driver 800 includes a first current source 810 to provide a bias current I_{off} that corresponds to the OFF state of the VCSEL 805 and a second current source 815 to provide a current Iₒₙ−I_{off} so that the sum of the currents provided by the first current source 810 and the second current source 815 provide the drive current Iₒₙ that corresponds to the ON state of the VCSEL 805.

The current-steered driver 800 differs from the driver 700 shown in FIG. 7 by including a third current source 820 that provides a current Iₒₙ−I_{off}. A switch 825 is used to selectively couple the VCSEL 805 or the third current source 820 in series with the second current source 815. In the OFF state, the switch 825 is set so that the VCSEL 805 is coupled in series with the first current source 810 and the third current source 820 is coupled in series with the second current source 815. The current flowing through the VCSEL 805 is I_{off} and the current flowing through the third current source is Iₒₙ−I_{off} Thus, the total current flowing from the high-voltage supply nodes to ground is Iₒₙ. In the ON state, the switch 825 is set so that the VCSEL 805 is coupled in series with the first current source 810 and the second current source 815. The third current source 820 is not coupled into the driver. The current flowing through the VCSEL 805 is Iₒₙ and no current is flowing through the third current source. Thus, the total current flowing from the high-voltage supply nodes to ground is Iₒₙ. Consequently, the total current flowing through the current-steered driver 800 remains constant independent of the state of the switch 825.

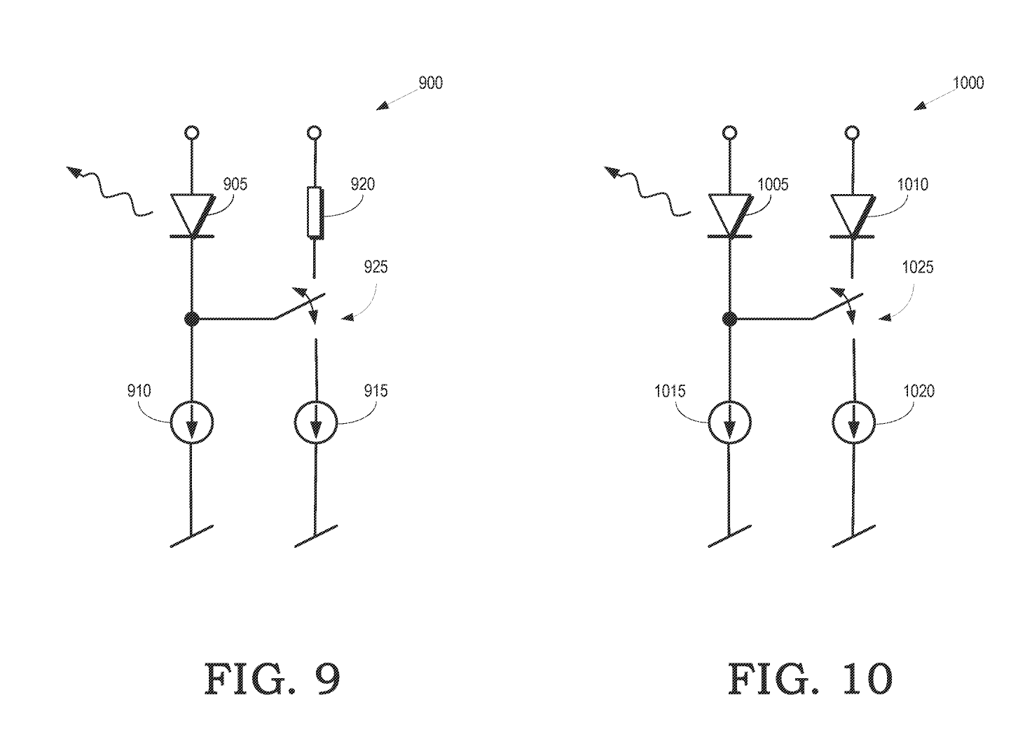

FIG. 9 is a block diagram of a current-steered driver 900 that includes a dummy impedance according to some embodiments. The driver 900 includes a first current source 910 to provide a bias current I_{off} that corresponds to the OFF state of the VCSEL 905 and a second current source 915 to provide a current Iₒₙ−I_{off}. A third current source is implemented as an impedance 920 that provides a current Iₒₙ−I_{off}. The impedance 920 is selected to match an impedance of the VCSEL 905. A switch 925 is used to selectively couple the VCSEL 905 or the impedance 920 in series with the second current source 915. As discussed herein, the total current flowing through the current-steered driver 900 remains constant independent of the state of the switch 925.

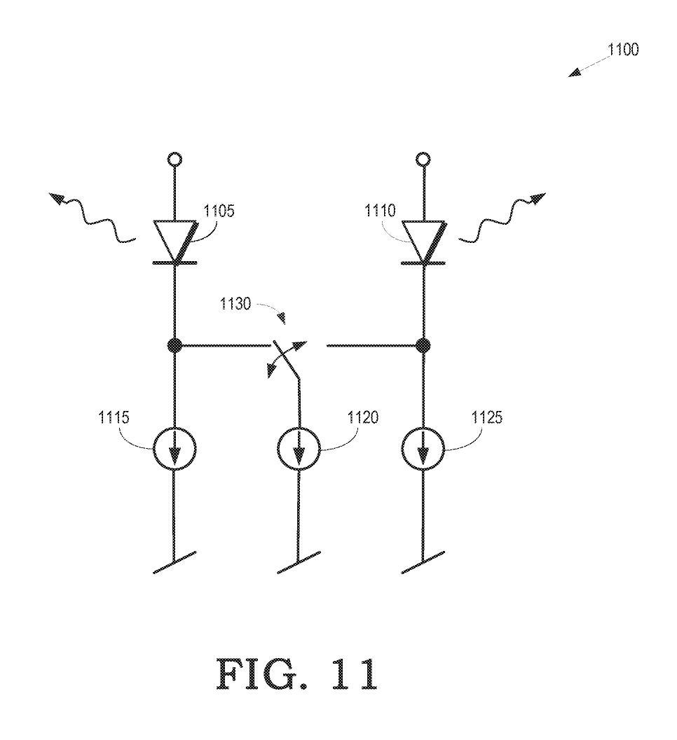

FIG. 10 is a block diagram of a current-steered driver 1000 that includes matched VCSELs 1005, 1010 according to some embodiments. The driver 1000 includes a first current source 1015 to provide a bias current I_{off} that corresponds to the OFF state of the VCSEL 1005 and a second current source 1020 to provide a current Iₒₙ−I_{off}. The VCSELs 1010 acts as a third current source provides a current Iₒₙ−I_{off}. The parameters of the VCSEL 1010 are selected to match the parameters of the VCSEL 1005 so that the VCSELs 1005, 1010 are substantially identical. A switch 1025 is used to selectively couple the VCSEL 1005 or the VCSEL 1010 in series with the second current source 1020. As discussed herein, the total current flowing through the current-steered driver 1000 remains constant independent of the state of the switch 1025 and the state of the VCSEL 1005.

FIG. 11 is a block diagram of a current-steered driver 1100 that drives matched VCSELs 1105, 1110 in response to complementary bitstream values according to some embodiments. The driver 1100 includes a first current source 1115 to provide a bias current I_{off} that corresponds to the OFF state of the VCSEL 1105 and a second current source 1120 to provide a current Iₒₙ−I_{off}. The driver 1100 also includes a third current source 1125 to provide a bias current I_{off} that corresponds to the OFF state of the VCSEL 1110. The parameters of the VCSEL 1110 are selected to match the parameters of the VCSEL 1105 so that the VCSELs 1105, 1110 are substantially identical. For example, the VCSELs 1105, 1110 may be fabricated using the same fabrication process.

A switch 1130 is used to selectively couple the VCSEL 1105 or the VCSEL 1110 in series with the third current source 1125. The switch 1130 can be in one of two states. In the first state, the switch 1130 couples the VCSEL 1105 to the first current source 1115 and the third current source 1125 so that a current Iₒₙ is driving the VCSEL 1105 to produce an optical signal that corresponds to the ON state of the VCSEL 1105. A bias current I_{off} is driving the VCSEL 1110 to produce an optical signal that corresponds to the OFF state of the VCSEL 1110. In the second state, the switch 1130 couples the VCSEL 1110 to the second current source 1120 and the third current source 1125 so that a current Iₒₙ is driving the VCSEL 1110 to produce an optical signal that corresponds to the ON state of the VCSEL 1110. A bias current I_{off} is driving the VCSEL 1105 to produce an optical signal that corresponds to the OFF state of the VCSEL 1105. Consequently, the total current flowing through the current-steered driver 1100 remains constant independent of the state of the switch 1130.

The state of the switch 1130 may be controlled by an input data stream so that the optical signals generated by the VCSEL 1105 are representative of the input data stream. For example, the switch 1130 may be placed in the first state in response to a value of a bit in the input data stream being equal to “1” and the switch 1130 may be placed in the second state in response to a value of a bit in the input data stream being equal to “0.” Thus, the VCSEL 1105 produces an optical signal corresponding to the ON state of the VCSEL 1105 when the value of the bit in the input data stream is equal to “1” or the OFF state of the VCSEL 1105 when the value of the bit in the input data stream is equal to “0.” The optical signals generated by the VCSEL 1110 are representative of the complement of the input data stream. For example, the VCSEL 1110 produces an optical signal corresponding to the OFF state of the VCSEL 1110 when the value of the bit in the input data stream is equal to “1” or the ON state of the VCSEL 1110 when the value of the bit in the input data stream is equal to “0.”

The optical signals produced by the VCSELs 1105, 1110 can be coupled to separate optical fibers to transmit optical signals to different endpoints. The current-steered driver 1100 and the VCSELs 1105, 1110 may therefore be implemented in some embodiments of the dual endpoint transceivers 230 shown in FIG. 2, the dual endpoint optical transmitter shown in FIG. 3, or the transmitter 610 shown in FIG. 6. Relative to embodiments of the transmitters 410, 510 shown in FIG. 4 and FIG. 5, embodiments of the driver 700 shown in FIG. 7, or embodiments of the current-steered drivers 800, 900, 1000 shown in FIG. 8, FIG. 9, and FIG. 10, the current-steered driver 1100 shown in FIG. 11 require substantially no additional overhead to produce the additional optical signal representative of the bitstream. Thus, a VCSEL-based dual endpoint transmitter formed using the current-steered driver 1100 may have the same power consumption as a conventional VCSEL-based single endpoint transmitter.

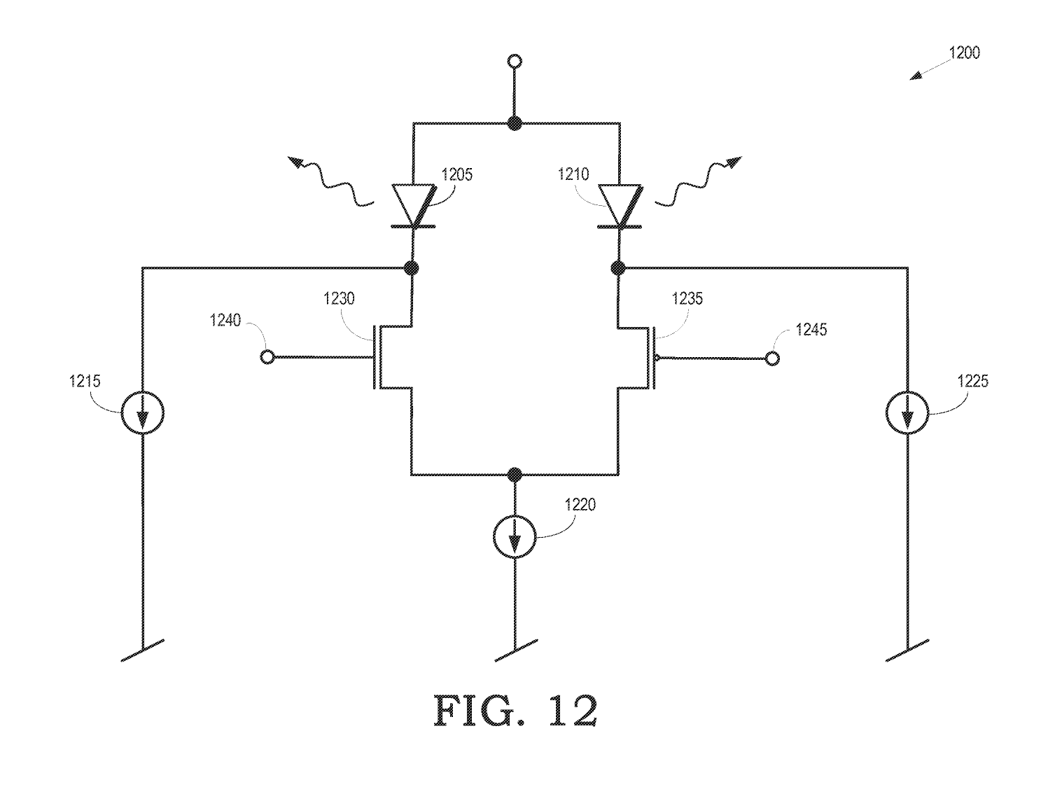

FIG. 12 is a block diagram of a current-steered driver 1200 that drives matched VCSELs 1205, 1210 using a transistor-based switch according to some embodiments. The current-steered driver 1200 and the VCSELs 1205, 1210 may be implemented in some embodiments of the dual endpoint transceivers 230 shown in FIG. 2, the dual endpoint optical transmitter shown in FIG. 3, or the transmitter 610 shown in FIG. 6. The driver 1200 includes a first current source 1215 to provide a bias current I_{off} that corresponds to the OFF state of the VCSEL 1205 and a second current source 1220 to provide a current Iₒₙ−I_{off}. The driver 1200 also includes a third current source 1225 to provide a bias current I_{off} that corresponds to the OFF state of the VCSEL 1210. The parameters of the VCSEL 1210 are selected to match the parameters of the VCSEL 1205 so that the VCSELs 1205, 1210 are substantially identical. For example, the VCSELs 1205, 1210 may be fabricated using the same fabrication process. The current-steered driver 1200 may operate in two states: a first state in which the VCSEL 1205 is driven by the current Iₒₙ and the VCSEL 1210 is driven by the current I_{off} and a second state in which the VCSEL 1205 is driven by the current I_{off} and the VCSEL 1210 is driven by the current Iₒₙ.

Switching between the first state and the second state of the current-steered driver 1200 is performed by transistors 1230, 1235. In the illustrated embodiment, the transistors 1230, 1235 are opposite types. For example, the transistor 1230 may be a PMOS transistor and the transistor 1235 may be an NMOS transistor. An electrical signal corresponding to an input data stream may be applied to the nodes 1240, 1245 that are coupled to gates of the transistors 1230, 1235, respectively. For example, the current-steered driver 1200 may be placed in the first state in response to a value of a bit in the input data stream being equal to “1,” which turns on the transistor 1230 and turns off the transistor 1235. The current-steered driver 1200 may be placed in the second state in response to a value of a bit in the input data stream being equal to “0,” which turns off the transistor 1230 and turns on the transistor 1235. Thus, the VCSEL 1205 produces an optical signal corresponding to the ON state of the VCSEL 1205 when the value of the bit in the input data stream is equal to “1” or the OFF state of the VCSEL 1205 when the value of the bit in the input data stream is equal to “0.” The optical signals generated by the VCSEL 1210 are representative of the complement of the input data stream. For example, the VCSEL 1210 produces an optical signal corresponding to the OFF state of the VCSEL 1210 when the value of the bit in the input data stream is equal to “1” or the ON state of the VCSEL 1210 when the value of the bit in the input data stream is equal to “0.” Instead of using different types of transistors 1230, 1235, some embodiments may support transmission of the complementary optical signals using the same type of transistors 1230, 1235 and providing complementary values of the input data stream to the nodes 1240, 1245.

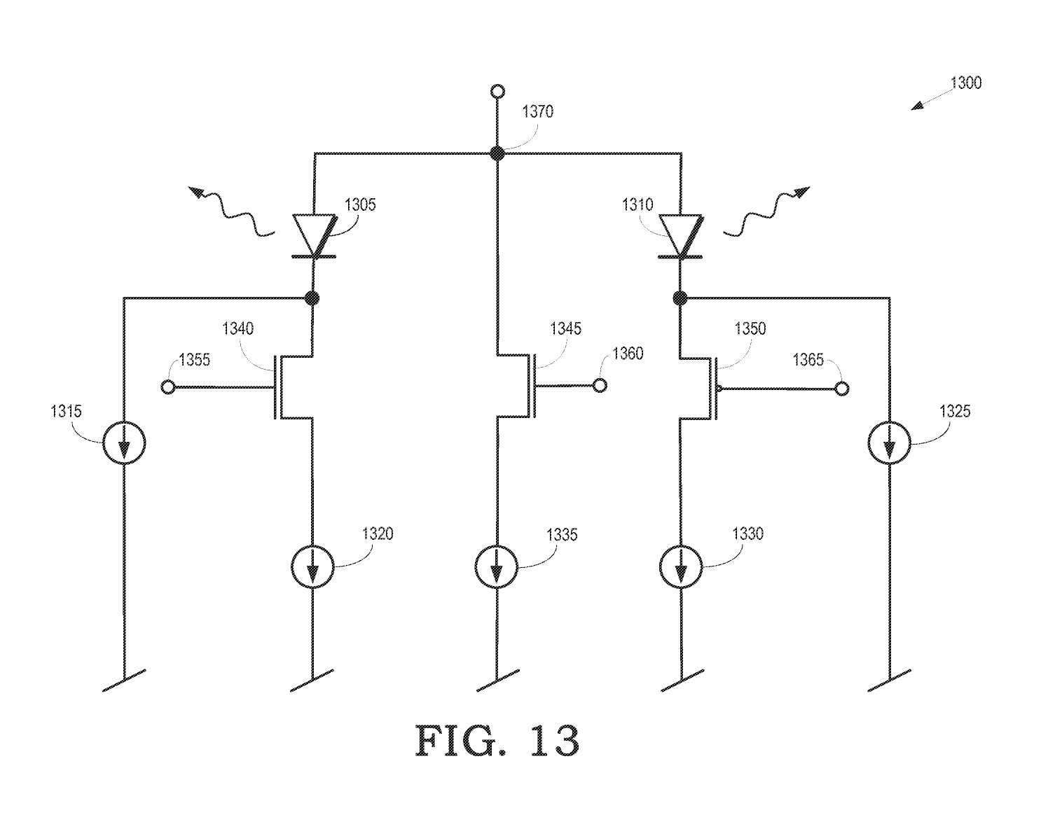

FIG. 13 is a block diagram of a current-steered driver 1300 that drives matched VCSELs 1305, 1310 with different drive currents according to some embodiments. The current-steered driver 1300 and the VCSELs 1305, 1310 may be implemented in some embodiments of the dual endpoint transceivers 230 shown in FIG. 2, the dual endpoint optical transmitter shown in FIG. 3, or the transmitter 610 shown in FIG. 6. The driver 1300 includes a first current source 1315 to provide a bias current I_{off} that corresponds to the OFF state of the VCSEL 1305 and a second current source 1320 to provide a current Iₒₙ₁−I_{off}, where Iₒₙ₁ is the ON drive current for the VCSEL 1305. The driver 1300 also includes a third current source 1325 to provide a bias current I_{off} that corresponds to the OFF state of the VCSEL 1310 and a fourth current source 1330 to provide a current Iₒₙ₂−I_{off}, where Iₒₙ₂ is the ON drive current for the VCSEL 1310. A fifth current source 1335 provides a current Iₒₙ₂−Iₒₙ₁ so that the total current flow through the current-steered driver 1300 remains substantially constant independent of the state of the switching elements, as discussed herein. The parameters of the VCSEL 1310 are selected to match the parameters of the VCSEL 1305 so that the VCSELs 1305, 1310 are substantially identical. For example, the VCSELs 1305, 1310 may be fabricated using the same fabrication process.

The current-steered driver 1300 may operate in two states: a first state in which the VCSEL 1305 is driven by the current Iₒₙ₁ and the VCSEL 1310 is driven by the current I_{off} and a second state in which the VCSEL 1305 is driven by the current I_{off} and the VCSEL 1310 is driven by the current Iₒₙ₂. Switching between the first state and the second state of the current-steered driver 1300 is performed by transistors 1340, 1345, 1350. In the illustrated embodiment, the transistors 1340, 1345 are of the same type and the transistor 1350 is an opposite type. For example, the transistor 1340 may be a PMOS transistor, the transistor 1345 may be a PMOS transistor, and the transistor 1350 may be an NMOS transistor. An electrical signal corresponding to an input data stream may be applied to the nodes 1355, 1360, 1365 that are coupled to gates of the transistors 1340, 1345, 1350, respectively. As discussed herein, the current-steered driver 1300 may be selectively placed in the first state in response to a value of a bit in the input data stream equal to “1” and in the second state in response to a value of a bit in the input data stream equal to “0.” Instead of using different types of transistors 1340, 1350, some embodiments may support transmission of complementary optical signals from the VCSELs 1305, 1310 using the same type of transistors 1340, 1350 and providing complementary values of the input data stream to the nodes 1355, 1365.

The current-steered driver 1300 differs from the current-steered driver 1200 shown in FIG. 12 because the VCSELs 1305, 1310 are driven by different drive currents. Selectively coupling the fifth current source 1335 to the node 1370 accounts for the difference between the respective drive currents Iₒₙ₁ and Iₒₙ₂ of the VCSELs 1305, 1310 so that a substantially constant total current flows through the current-steered driver 1300 independent of the state of the current-steered driver 1300. For example, the fifth current source 1335 is coupled to the node 1370 in response to a value of a bit in the input data stream being equal to “1,” in which case the current-steered driver 1300 is in the first state and the total current flowing through the current-steered driver 1300 is Iₒₙ₂+I_{off}. The fifth current source 1335 is disconnected from the node 1370 in response to a value of a bit in the input data stream being equal to “0,” in which case the current-steered driver 1300 is in the second state and the total current flowing to the current-steered driver 1300 is again Iₒₙ₂+I_{off}.

Some embodiments of the current-steered drivers 1100, 1200, 1300 shown in FIGS. 11-13, respectively, are used to provide drive currents to a pair of lasers (such as VCSELs) that can be coupled to optical fibers for transmission to other devices. However, other embodiments of current-steered drivers may be used to support multi-endpoint transmitters having more than two lasers. For example, additional lasers and current sources may be incorporated into the current-steered drivers 1100, 1200, 1300, and additional switches may be used to selectively interconnect the lasers and current sources to generate optical signals representative of a bitstream or a complement of the bitstream. The additional lasers may also be coupled to provide the optical signals to additional optical fibers that are connected to other endpoints.

In some embodiments, certain aspects of the techniques described above may implemented by one or more processors of a processing system executing software. The software comprises one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium may be in source code, assembly language code, object code, or other instruction format that is interpreted or otherwise executable by one or more processors.

A computer readable storage medium may include any storage medium, or combination of storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. An apparatus comprising:
a first laser to couple to a first optical fiber;
a second laser to couple to a second optical fiber; and
a current-steered driver connected to the first and second lasers to provide a first current representative of a bitstream to drive the first laser and to provide a second current representative of a complement of the bitstream to drive the second laser.

2. The apparatus of claim 1, wherein the first and second lasers are vertical-cavity surface-emitting lasers (VCSELs).

3. The apparatus of claim 1, wherein the current-steered driver comprises:
a first current source coupled in series with the first laser to provide an OFF current corresponding to an OFF state of the first laser;
a second current source to provide a current equal to a difference between an ON current corresponding to the ON state of the first laser and the OFF current;
a third current source coupled in series with the second laser to provide a current equal to the OFF current; and
a switch to selectively couple the second current source in series with the first laser or the second laser.

4. The apparatus of claim 3, wherein the switch comprises:
at least one first transistor to receive a first electrical signal representative of the bitstream; and
at least one second transistor to receive a second electrical signal representative of the complement of the bitstream.

5. The apparatus of claim 1, wherein the current-steered driver comprises:
a first current source coupled in series with the first laser to provide an OFF current corresponding to an OFF state of the first laser;
a second current source to provide a current equal to a difference between a first ON current corresponding to the ON state of the first laser and the OFF current;
a third current source to provide a current equal to a difference between the first ON current and a second ON current corresponding to the ON state of the second laser;
a fourth current source to provide a current equal to a difference between the second ON current and the OFF current;
a fifth current source coupled in series with the second laser to provide the OFF current; and
a switch to selectively couple one of: the second current source in series with the first laser; or the third current source in parallel with the second laser and the fourth current source in series with the second laser.

6. The apparatus of claim 5, wherein the switch comprises:
at least one first transistor coupled in series with the first laser and the second current source, wherein the at least one first transistor is to receive a first electrical signal representative of the bitstream;
at least one second transistor coupled in parallel with the first laser and the second laser, wherein the at least one second transistor is to receive the first electrical signal; and
at least one third transistor coupled in series with the second laser and the fourth current source, wherein the at least one third transistor is to receive a second electrical signal representative of the complement of the bitstream.

7. The apparatus of claim 5, further comprising:
a voltage node; and
a ground node, wherein the first laser and the second laser are connected in parallel between the voltage node and the switch in the current-steered driver, and wherein the current-steered driver is connected to the ground node.

8. The apparatus of claim 7, wherein a total current flowing from the voltage node to the ground node is substantially constant independent of a state of the switch.

9. A method comprising:
providing, from a current-steered driver, a first current representative of a bitstream to drive a first laser coupled to a first optical fiber; and
providing a second current representative of a complement of the bitstream to drive a second laser coupled to a second optical fiber.

10. The method of claim 9, wherein providing the first current to the first laser comprises providing the first current to a first vertical-cavity surface-emitting laser (VCSEL), and wherein providing the second currents to the second layer comprises providing the second current to a second VCSEL.

11. The method of claim 9, further comprising:
providing, from a first current source coupled in series with the first laser, an OFF current corresponding to an OFF state of the first laser;
providing, from a second current source, a current equal to a difference between an ON current corresponding to the ON state of the first laser and the OFF current;
providing, from a third current source coupled in series with the second laser, a current equal to the OFF current; and
selectively coupling the second current source in series with the first laser or the second laser.

12. The method of claim 11, wherein selectively coupling the second current source in series with the first laser or the second laser comprises:
providing a first electrical signal representative of the bitstream to at least one first transistor; and
providing a second electrical signal representative of the complement of the bitstream at least one second transistor.

13. The method of claim 9, further comprising:
providing, from a first current source coupled in series with the first laser, an OFF current corresponding to an OFF state of the first laser;
providing, from a second current source, a current equal to a difference between a first ON current corresponding to the ON state of the first laser and the OFF current;
providing, from a third current source, a current equal to a difference between the first ON current and a second ON current corresponding to the ON state of the second laser;
providing, from a fourth current source, a current equal to a difference between the second ON current and the OFF current;
providing, from a fifth current source coupled in series with the second laser, the OFF current; and
selectively coupling the second current source in series with the first laser or coupling the third current source in parallel with the second laser and the fourth current source in series with the second laser.

14. The method of claim 13, wherein selectively coupling comprises:
providing a first electrical signal representative of the bitstream to at least one first transistor coupled in series with the first laser and the second current source;
providing the first electrical signal to at least one second transistor coupled in parallel with the first laser and the second laser; and
providing a second electrical signal representative of the complement of the bitstream to at least one third transistor coupled in series with the second laser and the fourth current source.

15. The method of claim 9, wherein providing the first current and the second current comprises providing, as the first current and the second current, currents that flow between a voltage node to a ground node, wherein the first laser and the second laser are connected in parallel between the voltage node and the current-steered driver, and wherein the current-steered driver is connected to the ground node.

16. The method of claim 15, wherein providing the first current and the second current comprises providing a total current that is substantially constant independent of state of a switching state of the current-steered driver.

17. An apparatus comprising:
a plurality of lasers to couple to a corresponding plurality of optical fibers; and
a current-steered driver connected to the plurality of lasers to selectively provide first currents representative of a bitstream to drive a first portion of the plurality of lasers and second currents representative of a complement of the bitstream to drive a second portion of the plurality of lasers.

18. The apparatus of claim 17, wherein the plurality of lasers are vertical-cavity surface-emitting lasers (VCSELs).
